(19) United States
(12) Patent Application Publication
(10) Pub. No.: US 2010/0229934 A1
(43) Pub. Date: Sep. 16, 2010

(54) Solar cell and method for the same

(75) Inventor: Taek-Yong Jang, Suwon-si (KR)

Correspondence Address: MANNAVA & KANG, P.C., 11240 WAPLES MILL ROAD, Suite 300, FAIRFAX, VA, 22030, US

(73) Assignee: TG SOLAR CORPORATION, Suwon-si, Gyeonggi-do (KR)

(21) Appl. No.: 12/669,235

(22) PCT Filed: Jul. 31, 2008
(86) PCT No.: PCT/KR2008/004464

§ 371 Date: Jan. 15, 2010

(30) Foreign Application Priority Data
Jul. 31, 2007 (KR) 10-2007-0077147

(51) Int. Cl. H01L 31/04; H01L 31/028; H01L 31/18; H01L 31/0224

(52) U.S. Cl. 136/256; 136/261; 438/98; 438/72; 257/E31.001; 257/E31.011; 257/E31.124

(57) ABSTRACT

A polycrystalline silicon solar cell and its manufacturing method are disclosed. The polycrystalline silicon solar cell in according with the present invention is formed by crystallizing amorphous silicon, in which a metal catalyst is used to lower crystallization temperature. The solar cell in according with the present invention is characterized by comprising a plurality of polycrystalline silicon layers, wherein at least one of the plurality of polycrystalline silicon layers contains a metal component.

### TECHNICAL FIELD

The present invention relates to silicon solar cells and a method for manufacturing the same, and more specifically, to high-efficiency polycrystalline silicon solar cells and a method for manufacturing the same.

### BACKGROUND ART

Solar cells are key elements in photovoltaic technologies that convert solar light directly into electricity, and are widely used in a variety of applications from the universe to homes.

A solar cell is basically a diode having a p-n junction and its operation principle is as follows. When solar light having an energy greater than the band gap energy of a semiconductor is incident on the p-n junction of a solar cell, electron-hole pairs are generated. By an electric field created at the p-n junction, the electrons are transferred to the n layer, while the holes are transferred to the p layer, thereby generating photovoltaic force between the p and n layers. When both ends of the solar cell are connected to a load or a system, electric power is produced as current flows.

Solar cells are classified into a variety of types depending on the materials used to form an intrinsic layer (i.e., light absorption layer). In general, silicon solar cells having intrinsic layers made of silicon are the most popular ones. There are two types of silicon solar cells: substrate-type (monocrystalline or polycrystalline) solar cells and thin film type (amorphous or polycrystalline) solar cells. Besides these two types of solar cells, there are CdTe or CIS (CuInSe₂) compound thin film solar cells, solar cells based on III-V family materials, dry-sensitized solar cells, organic solar cells, and so on.

Monocrystalline silicon substrate-type solar cells have remarkably high conversion efficiency compared to other types of solar cells, but have a fatal weakness in that their manufacturing costs are very high due to the use of monocrystalline silicon wafers. Also, polycrystalline silicon substrate-type solar cells can be produced at relatively low manufacturing costs, but they are not much different from monocrystalline silicon substrate-type solar cells because solar cells of both types are made out of bulk raw materials. Therefore, their raw material price is expensive and their manufacturing process is complicate, thus making it difficult to cut down the manufacturing costs.

As one solution to resolve the deficiencies of those substrate-type solar cells, thin film type silicon solar cells have drawn a lot of attentions mainly because their manufacturing costs are remarkably low by depositing a silicon thin film as an intrinsic layer on a substrate such as glass. In effect, the thin film type silicon solar cells can be produced about 100 times thinner than the substrate-type silicon solar cells.

Amorphous silicon thin film solar cells were firstly developed out of the thin film silicon solar cells and are started to be used in homes. Since amorphous silicon can be formed by chemical vapor deposition (CVD), it greatly contributes for mass-production of amorphous silicon solar cells and low manufacturing costs. However, there is a problem that amorphous silicon thin film solar cells are too low in their conversion efficiency compared to that of the substrate-type silicon solar cells. One possible reason for the low efficiency of amorphous silicon solar cells is because most silicon atoms within amorphous silicon exist in non-bonded states, that is, amorphous silicon has a lot of silicon atoms with dangling bonds. In order to reduce such dangling bonds, amorphous silicon may be treated in hydrogen to form hydrogenated amorphous silicon (a-Si:H) with hydrogen atoms attached to silicon atoms with dangling bonds, such that the localized state density is reduced to increase the efficiency. However, the hydrogenated amorphous silicon (s-Si:H) is highly sensitive to light, so solar cells made out of such materials are aged and their efficiency is also impaired (i.e., Staebler-Wronski effect), thereby revealing the limits of use in large scale electric power generation.

Meanwhile, polycrystalline silicon thin film solar cells have been developed to complement the shortcomings of the amorphous silicon thin film solar cell as noted above. With the use of polycrystalline silicon for an intrinsic layer, polycrystalline silicon thin film solar cells exhibit more superior performance than amorphous silicon thin film solar cells using amorphous silicon for an intrinsic layer.

### DISCLOSURE

### Technical Problem

However, a problem with such polycrystalline silicon thin film solar cells is that it is not easy to prepare polycrystalline silicon. To be more specific, polycrystalline silicon is usually obtained through a solid phase crystallization process of amorphous silicon. The solid phase crystallization of amorphous silicon involves a high-temperature (e.g., 600° C. or higher) annealing over a period of 10 hours, which is not suitable for mass-production of solar cells. Especially, an expensive quartz substrate has to be used, instead of the regular glass substrate, to sustain such a high temperature of 600° C. or higher during the solid phase crystallization process, but this can increase the manufacturing costs of solar cells. Moreover, the solid phase crystallization process is known to degrade the properties and performance of a solar cell because polycrystalline silicon grains tend to grow in an irregular orientation and are very irregular in size.

### Technical Solution

It is, therefore, an object of the present invention to provide a polycrystalline silicon thin film solar cell with high conversion efficiency, and a method for manufacturing the same.

Another object of the present invention is to provide a mass-producible polycrystalline silicon thin film solar cell and a method for manufacturing the same.

### ADVANTAGEOUS EFFECTS

With the use of a polycrystalline silicon layer, a solar cell in accordance with the present invention can improve conversion efficiency.

In addition, as the polycrystalline silicon layer is formed on a regular glass substrate, solar cells in accordance with the present invention can be produced at lower manufacturing costs.

Furthermore, the solar cell manufacturing method in accordance with the present invention can easily be applied to the mass production of large-scale solar cells.

### DESCRIPTION OF DRAWINGS

The above and other objects and features of the present invention will become apparent from the following description of the preferred embodiments given in conjunction with the accompanying drawings, in which:

FIG. 1 shows the configuration of a solar cell in accordance with one embodiment of the present invention.

### BEST MODE FOR THE INVENTION

In accordance with one aspect of the present invention, there is provided a solar cell comprising a plurality of silicon layers, wherein at least one of the plurality of silicon layers contains a metal component.

In accordance with another aspect of the present invention, there is provided a solar cell, comprising: a substrate; a first conductive type silicon layer I formed on the substrate; a second conductive type silicon layer II formed on the silicon layer I; and a second conductive type silicon layer III formed on the silicon layer II, wherein at least one of the silicon layers I, II, and III contains a metal component.

In accordance with still another aspect of the present invention, there is provided a solar cell, comprising: a substrate; a first conductive type silicon layer I formed on the substrate; a first conductive type silicon layer II formed on the silicon layer I; and a second conductive type silicon layer III formed on the silicon layer II, wherein at least one of the silicon layers I, II, and III contains a metal component.

The substrate may comprise glass, plastics, silicon and metal.

If the first conductive type is an n-type, the second conductive type may be a p-type; and if the first conductive type is a p-type, the second conductive type may be an n-type.

At least one of the silicon layers I, II, and III may be a crystalline silicon layer.

The metal component may include Ni, Al, Ti, Ag, Au, Co, Sb, Pd, Cu, or a combination thereof.

The solar cell may further comprise an antireflective layer between the substrate and the silicon layer I.

In accordance with still another aspect of the present invention, there is provided a method for manufacturing a solar cell comprising a plurality of silicon layers, wherein at least one of the plurality of silicon layers is crystallized in presence of a metal component.

In accordance with still another aspect of the present invention, there is provided a method for manufacturing a solar cell, comprising the steps of: preparing a substrate; forming a first conductive type silicon layer I on the substrate; forming a second conductive type silicon layer II on the silicon layer I; and forming a second conductive type silicon layer III on the silicon layer II, wherein a metal layer is formed on at least one of the silicon layers I, II, and III, and the method further comprises the step of: annealing the silicon layers I, II, and III.

In accordance with still another aspect of the present invention, there is provided a method for manufacturing a solar cell, comprising the steps of: preparing a substrate; forming a first conductive type silicon layer I on the substrate; forming a first conductive type silicon layer II on the silicon layer I; and forming a second conductive type silicon layer III on the silicon layer II, wherein a metal layer is formed on at least one of the silicon layers I, II, and III, and the method further comprises the step of: annealing the silicon layers I, II, and III.

The substrate may comprise glass, plastics, silicon and metal.

If the first conductive type is an n-type, the second conductive type may be a p-type; and if the first conductive type is a p-type, the second conductive type may be an n-type.

At least one of the silicon layers I, II, and III may be crystallized by an annealing process.

The metal layer may include Ni, Al, Ti, Ag, Au, Co, Sb, Pd, Cu, or a combination thereof.

The method may further comprise the step of: forming an antireflective layer between the substrate and the silicon layer I.

The silicon layers I, II, and III may be formed by a method selected from low pressure chemical vapor deposition (LPCVD), plasma enhanced chemical vapor deposition (PECVD), and hot wire chemical vapor deposition (HWCVD).

The metal layer may be formed by a method selected from LPCVD, PECVD, atomic layer deposition (ALD), and sputtering.

The thickness of the metal layer may be adjusted to control an amount of residual metal within at least one of the silicon layers I, II, and III.

### MODE FOR THE INVENTION

Hereinafter, an exemplary embodiment of the present invention will be explained in detail with reference to the accompanying drawing.

A polycrystalline silicon thin film solar cell in accordance with the present invention is characterized by using a metal catalyst to form a polycrystalline silicon layer in a manner to lower crystallization temperature. Over a long period of time, a method that crystallizes amorphous silicon using a metal catalyst (what is called an MIC (metal induced crystallization) method) has been used for polycrystalline silicon TFTs (thin film transistors), which serve as drive elements of flat displays such as LCDs. In other words, the most crucial process in the fabrication of a polycrystalline silicon TFT is associated with the crystallization of amorphous silicon at a low temperature, wherein, in particular, lowering the crystallization temperature is desired. While a variety of processes have been suggested to form polycrystalline silicon within a short amount of time at a low temperature, it was the MIC method that drew much attention after the method was known to be applicable to mass production by lowering the crystallization temperature. Although the crystallization process using a metal catalyst could be carried out at a low temperature, it results in a significant increase in leakage current due to a considerable amount of metal present in the active region of a TFT. Because of this, it is virtually impossible to apply the MIC method directly to the fabrication of polycrystalline silicon TFTs.

In view of the foregoing, the inventor(s) of the present invention noticed that if the MIC method for preparing polycrystalline silicon using a metal catalyst is applied to the fabrication of a polycrystalline silicon layer of a solar cell, the leakage current caused by metal contamination might not be as serious in the solar cell as in the TFT. That is, the polycrystalline silicon layer in a solar cell does not really require a high-precision control of electric properties as much as the polycrystalline silicon layer applied to the active region of a TFT does. Therefore, even if there may be metal contamination, it will not cause a significant problem.

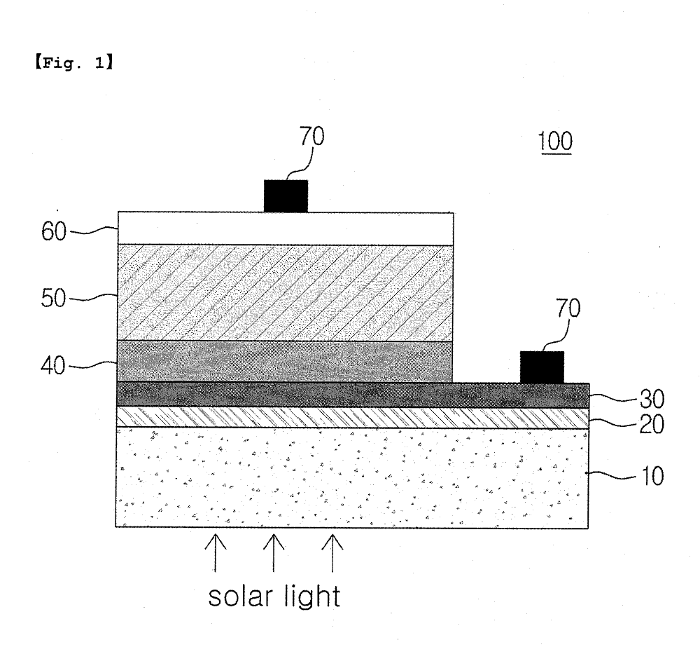

FIG. 1 illustrates the configuration of a solar cell 100 in accordance with one embodiment of the present invention. As shown in FIG. 1, the solar cell 100 includes an antireflective layer 20, a transparent conductive layer 30, a p+ type silicon layer 40, an n− type silicon layer 50, an n+ type silicon layer 60, and an electrode 70, which are staked sequentially in a multilayered manner on a substrate 10.

For the solar cell 100 of this embodiment, the substrate 10 is preferably made of a transparent material, such as, glass or plastics, in order to absorb solar light. The antireflective layer 20 serves to prevent deterioration in the efficiency of the solar cell by making it sure that incident solar light through the substrate 10 is reflected to the outside immediately without being absorbed by a silicon layer. Examples of a material for the antireflective layer 20 may include, but are not limited to, silicon oxides and silicon nitrides. The transparent conductive layer 30 permeates solar light and serves to electrically couple the p+ type silicon layer 40 to the electrode 70. To this end, the transparent conductive layer 30 may include ITO (Indium Tin Oxide) for example.

On the transparent conductive layer 30 is a three-layer silicon structure composed of the p+ type silicon layer 40, the n− type silicon layer 50, and the n+ type silicon layer 60, which are sequentially laminated to form the basic p-i-n structure for a thin film silicon solar cell. The p-i-n structure is formed by doping an impurity at a low density between a high-doped p+ type silicon layer 40 and a high-doped n+ silicon layer 60, thereby obtaining a relatively insulating n− type silicon layer 50 compared to the p+ type silicon layer 40 and the n+ type silicon layer 60. A typical solar cell is designed to let incident solar light enter from the p-side.

As explained above, while the solar cell in accordance with the present invention took the p-i-n structure as its basic structure, the present invention is not limited thereto but may take other structures such as a n-i-p structure (i.e., a laminate structure composed of n+ silicon layer/p− silicon layer/p+ silicon layer). In case of the n-i-p structure, since solar light is incident from the p-side, i.e., the opposite side of the substrate, it is not absolutely necessary to make the substrate out of transparent materials like glass, but the substrate may be made out of silicon or metals for example.

Moreover, in accordance with the configuration of the solar cell of the present invention as noted earlier, the conductive type of the i-side silicon layer is opposite to the conductive type of the silicon layer in contact with the substrate, but the present invention is not limited thereto. That is, a solar cell may be configured by setting the i-side silicon layer to have the same conductive type as that of the silicon layer in contact with the substrate.

Overall, the solar cell in accordance with the present invention can take any of the following structures: p+ silicon layer/n− silicon layer/n+ silicon layer, n+ silicon layer/p− silicon layer/p+ silicon layer, p+ silicon layer/p− silicon layer/n+ silicon layer, and n+ silicon layer/n− silicon layer/p+ silicon layer, as can be seen from the substrate upward. Hereinafter, the description will be focused on the configuration shown in FIG. 1, i.e., p+ type silicon layer 40/n-type silicon layer 50/n+ type silicon layer 60.

Meanwhile, it is another feature of the solar cell 100 that at least one layer out of p+ type silicon layer 40/n− type silicon layer 50/n+ type silicon layer 60 is a polycrystalline silicon layer. It is preferable that all of p+ type silicon layer 40/n− type silicon layer 50/n+ type silicon layer 60 are made out of polycrystalline silicon. In short, the polycrystalline silicon thin film solar cell is advantageous because it can be mass produced at a remarkably low price through the thin film solar cell manufacturing process by using silicon the reserve amount of which is high as a raw material, and at the same time it exhibits an improved efficiency because polycrystalline silicon itself has a higher electron mobility than amorphous silicon.

The following is a detailed explanation about a manufacturing method of the solar cell 100 in accordance with one embodiment of the present invention.

In a first step, a substrate 10 is prepared. As noted earlier, it is desirable that the substrate 10 is made out of a transparent material such as glass. Also, the substrate 10 may undergo a surface texturing process to improve the efficiency of the solar cell 100. The texturing process is done to prevent the substrate surface of a solar cell from impairing its properties due to the optical loss in result of the reflection of incident light. Therefore, the texturing process mainly involves making the surface of a target substrate used in a solar cell rough, i.e., forming an irregular pattern on the surface of a substrate. Once the surface of the substrate becomes rough by texturing, the light that reflected once reflects again and lowers the reflectance of incident light such that a greater amount of light is captured to reduce the optical loss.

In a next step, an antireflective layer 20 is formed on the substrate 10. As discussed earlier, the antireflective layer 20 may include a silicon oxide or a silicon nitride, and may be formed by low pressure chemical vapor deposition (LPCVD), plasma enhanced chemical vapor deposition (PECVD), or the like.

In a following step, a transparent conductive layer 30 is formed on the antireflective layer 20. As mentioned above, the transparent conductive layer 30 may include ITO (Indium Tin Oxide), and may be formed by sputtering or the like.

In a subsequent step, p+ type silicon layer 40/n− type silicon layer 50/n+ silicon layer 60 are sequentially formed on the transparent conductive layer 30. This three-layer silicon laminate is formed or grown in an amorphous silicon state by LPCVD, PECVD, hot wire chemical vapor deposition (HWCVD), or the like. The three-layer silicon laminate is preferably n-type doped or p-type doped by in-situ doping during the formation of the amorphous silicon layer. In general, phosphorous (P) is used as an impurity for the n-type doping, and boron (B) or arsenic (As) is used as an impurity for the p-type doping. The thickness and doping concentration of the three-layer silicon laminate preferably follows the thickness and doping concentration of the typical p-i-n structure adopted in a polycrystalline silicon thin film solar cell.

In a next step, the p+ type silicon layer 40/n− type silicon layer 50/n+ type silicon layer 60 in the amorphous state are crystallized to form a polycrystalline p+ type silicon layer 40/n− type silicon layer 50/n+ type silicon layer 60.

The present invention uses the MIC method to crystallize the amorphous silicon to polycrystalline silicon. To this end, a metal layer is first deposited on an amorphous silicon layer and crystallization-annealing process is carried out. The metal layer is formed on at least one layer out of the p+ type silicon layer 40/n− type silicon layer 50/n+ type silicon layer 60 structure. The material for the metal layer may be selected from Ni, Al, Ti, Ag, Au, Co, Sb, Pd, and Cu, which are used singly or in combination of two or more. The metal layer is formed by LPCVD, PECVD, atomic layer deposition (ALD), sputtering or the like. The crystallization-annealing process is carried out in a typical annealing furnace, preferably under conditions of 400-700° C. for a period of 1 to 10 hours.

In the meantime, the amount of residual metal inside the polycrystalline silicon layer after the crystallization-annealing process using the MIC can be controlled by adjusting the amount of metal to be deposited on the amorphous silicon layer. One way of adjusting the amount of metal is to adjust the thickness of the metal layer being deposited on the amorphous silicon layer, but the present invention is not limited thereto. In some cases, the metal layer needs to be made even thinner than one atomic layer in order to keep the amount of residual metal within the polycrystalline silicon layer to a minimum. Here, making the metal layer thinner than one atomic layer means that, supposing the entire area of the amorphous silicon layer is not covered completely with the deposited metal layer, the metal layer is deposited on the amorphous silicon layer sparsely (the coverage rate<1) instead of being deposited continuously. In other words, in case where the metal layer is deposited at the coverage rate less than 1, for example, more metal atom can be deposited between metal atoms that are already deposited on the amorphous silicon layer.

Finally, an electrode 70 is formed on the transparent conductive layer 30 and on the n+ type silicon layer 60, respectively, to thereby obtain a complete form of polycrystalline silicon thin film solar cell 100. The electrode 70 is made out of a conductive material such as aluminum, and may be formed by thermal evaporation, sputtering, or the like.

While a single junction solar cell has been explained earlier as one embodiment of the present invention, the present invention is not limited thereto but may also include a double junction (called the so-called tandem structure) solar cell, a triple junction solar cell, etc., as another embodiment. That is to say, double and triple-junction solar cells or any other solar cells and a manufacturing method thereof should be deemed to belong to the scope of the present invention as long as at least one of polycrystalline silicon layers constituting a solar cell contains a metal component.

As explained so far, the polycrystalline silicon thin film solar cell 100 and its manufacturing method in accordance with the present invention are advantageous in that amorphous silicon is crystallized to polycrystalline silicon at a low temperature by the use of the MIC method, thereby making it possible to use ordinary glass as a substrate. Accordingly, the conversion efficiency of the solar cell is improved by polycrystalline silicon, while the manufacturing costs thereof can be reduced.

While the invention has been shown and described with respect to the preferred embodiments, it will be understood by those skilled in the art that various changes and modifications may be made without departing from the spirit and the scope of the invention as defined in the following claims.

1. (canceled)

2. A solar cell, comprising:
a substrate;
a first conductive type silicon layer I formed on the substrate;
a second conductive type silicon layer II formed on the silicon layer I; and
a second conductive type silicon layer III formed on the silicon layer II,
wherein at least one of the silicon layers I, II, and III is a crystalline silicon layer formed by annealing the silicon layers I, II and III after a metal layer is formed on at least one of the silicon layers I, II and III.

3. A solar cell, comprising:
a substrate;
a first conductive type silicon layer I formed on the substrate;
a first conductive type silicon layer II formed on the silicon layer I; and
a second conductive type silicon layer III formed on the silicon layer II,
wherein at least one of the silicon layers I, II, and III is a crystalline silicon layer formed by annealing the silicon layers I, II, and III after a metal layer is formed on at least one of the silicon layers I, II, and III.

4. The solar cell of claim 2 or 3, wherein the substrate comprises glass, plastics, silicon and metal.

5. The solar cell of claim 2 or 3, wherein if the first conductive type is an n-type, the second conductive type is a p-type; and if the first conductive type is a p-type, the second conductive type is an n-type.

6. (canceled)

7. The solar cell of claim 2 or 3, wherein the metal layer includes Ni, Al, Ti, Ag, Au, Co, Sb, Pd, Cu, or a combination thereof.

8. The solar cell of claim 2 or 3, further comprising:
an antireflective layer between the substrate and the silicon layer I.

9. (canceled)

10. A method for manufacturing a solar cell, comprising the steps of:
preparing a substrate;
forming a first conductive type silicon layer I on the substrate;
forming a second conductive type silicon layer II on the silicon layer I; and
forming a second conductive type silicon layer III on the silicon layer II,
wherein a metal layer is formed on at least one of the silicon layers I, II, and III, and the method further comprises the step of:
annealing the silicon layers I, II, and III.

11. A method for manufacturing a solar cell, comprising the steps of:
preparing a substrate;
forming a first conductive type silicon layer I on the substrate;
forming a first conductive type silicon layer II on the silicon layer I; and
forming a second conductive type silicon layer III on the silicon layer II,
wherein a metal layer is formed on at least one of the silicon layers I, II, and III, and the method further comprises the step of:
annealing the silicon layers I, II, and III.

12. The method of claim 10 or 11, wherein the substrate comprises glass, plastics, silicon and metal.

13. The method of claim 10 or 11, wherein if the first conductive type is an n-type, the second conductive type is a p-type; and if the first conductive type is a p-type, the second conductive type is an n-type.

14. The method of claim 10 or 11, wherein at least one of the silicon layers I, II, and III is crystallized by an annealing process.

15. The method of claim 10 or 11, wherein the metal layer includes Ni, Al, Ti, Ag, Au, Co, Sb, Pd, Cu, or a combination thereof.

16. The method of claim 10 or 11, further comprising the step of:
forming an antireflective layer between the substrate and the silicon layer I.

17. The method of claim 10 or 11, wherein the silicon layers I, II, and III are formed by a method selected from low pressure chemical vapor deposition (LPCVD), plasma enhanced chemical vapor deposition (PECVD), and hot wire chemical vapor deposition (HWCVD).

18. The method of claim 10 or 11, wherein the metal layer is formed by a method selected from LPCVD, PECVD, atomic layer deposition (ALD), and sputtering.

19. The method of claim 10 or 11, wherein a thickness of the metal layer is adjusted to control an amount of residual metal within at least one of the silicon layers I, II, and III.
